(19) United States
(12) Patent Application Publication
(10) Pub. No.: US 2006/0272802 A1
(43) Pub. Date: Dec. 7, 2006

(54) Cooling plate

(75) Inventors: Hitoshi Sakayori, Tsukuba (JP); Kouichi Isaka, Ishioka (JP); Masami Odakura, Tsukuba (JP); Katsumi Nomura, Tsuchiura (JP)

Correspondence Address: FOLEY AND LARDNER LLP;SUITE 500, 3000 K STREET NW, WASHINGTON, DC, 20007, US

(73) Assignee: HITACHI CABLE, LTD.

(21) Appl. No.: 11/399,466

(22) Filed: Apr. 7, 2006

(30) Foreign Application Priority Data
Jun. 7, 2005 (JP) 2005-166685

(51) Int. Cl. H05K 7/20

(52) U.S. Cl. 165/170; 165/80.4; 361/699; 257/714

(57) ABSTRACT

A cooling plate comprises a passage 6 for flowing a coolant by closing a groove 5 formed on a main body 2 with a lid 3. The lid 3 has a width greater than that of the groove 5 and has a convex portion 4 at least on one surface. The cooling plate can be used as a backing plate with little local deformation and long operation lifetime.

The present application is based on Japanese Patent Application No. 2005-166685 filed on Jun. 7, 2005, the entire contents of which are incorporated herein by reference.

### BACKGROUND OF THE INVENTION

1. Field of the Invention

This invention relates to a cooling plate, and more particularly, to a cooling plate having a coolant passage formed by a groove and a lid.

2. Description of the Related Art

The cooling plate is widely used in industrial fields and, for instance, used for a sputtering apparatus. The sputtering apparatus is used in a manufacturing process in various fields of electronics such as semiconductor devices, various sensors, magnetic recording media, optical recording media, and flat-panel displays. At this time, a backing plate to which a target material to be sputtered is adhered has a function as a cooling plate as well as a role of a backboard for the target material.

It is required that the backing plate has a high cooling ability. For example, in the above-mentioned sputtering apparatus, a high cooling ability is one of very important factors for the backing plate, since a quality (e.g. electrical and/or optical properties, etc.) of a thin film formed on a substrate is influenced by an efficient radiation of the heat generated at the sputtering target during the sputtering process.

More particularly, in a sputtering apparatus for manufacturing large-sized liquid crystal panels etc., a size of the sputtering target increases in accordance with an increase in size of a film forming substrate (i.e. a substrate on which a film is formed, for example, a glass plate), so that an amount of generated heat becomes larger. Therefore, a large-sized backing plate is used for cooling the target material.

The backing plate comprises a flat and smooth plate having a passage for flowing a coolant within, and cooling water cooled by a chiller is flown in this passage for cooling a target material. As a similar cooling plate having a passage for flowing a coolant in a plate, there are various water-cooling jackets and water-cooling chills etc. other than the backing plate.

FIG. 1 is a perspective view showing an example of a conventional backing plate. Moreover, FIG. 2 is a cross sectional view of the conventional backing plate shown in FIG. 1 cut along A-A line.

A conventional backing plate 71 comprises a main body 72 and a lid 73. A groove 75 is provided at the main body 72, and a passage 76 is formed by the lid 73 and the groove 75. A width of the groove 75 is W₂, and a width of an inlaid part is W₃. The lid 73 has a thickness t₁ and a width of W₂+W₃+W₃. Although the groove 75 is provided with an inlet and an outlet for a coolant, the illustration thereof is omitted. The backing plate 71 functions as an efficient cooling plate by supplying a cooling water etc. from one side of the passage 76 (the inlet for the coolant), and flowing the cooling water along the passages 76 which are positioned uniformly (with a predetermined interval) in the backing plate 71.

As a material of the backing plate 71, a metal such as pure copper, copper alloy, aluminum, aluminum alloy, titanium, and stainless steels can be used, and especially, pure copper and copper alloys with a high thermal conductivity are mostly used.

The backing plate 71 may be fabricated by joining and sealing the groove 75 (the main body 72) and the lid 73 by using a method such as electron beam welding, friction stir welding or wax welding method. Examples of method for fabricating the backing plate are disclosed by JP-A-2001-313357 and JP-A-2002-248584.

As mentioned above, the backing plate 71 is used in a sputtering apparatus for manufacturing a liquid crystal panel, etc., and bonded with a metallic or oxide based target material (not shown). The sputtering target is a kind of consumable supplies, which is exhausted sequentially by sputtering. When consumption of the target material reaches a serviceability limit, the used sputtering target is exchanged to another (new) one.

For effective radiating the heat generated at the sputtering target during the sputtering, a state of bonding (a heat contact condition) between the backing plate 71 and the target material is very important. Moreover, a flatness of a bonded surface and a flatness of a total structure are required.

As a material for joining the backing plate 71 with the target material, indium is mainly used. Herein, it is necessary to heat the backing plate 71 up to a melting point of indium. Such a process of joining is called as a bonding process.

As an example of the bonding process, a case where the metallic target material is bonded by using indium to the backing plate 71 made of copper. A heating condition for this case is to heat the backing plate 71 at about 230° C., such that indium is heated at a temperature higher than the melting point of indium (about 160° C.) and that a uniform bonding can be obtained.

In addition, expansion/shrinkage characteristics of the target material and the backing plate 71 are different from each other because of the difference in materials thereof. Therefore, so as to securely obtain the flatness after cooling and during the use in the sputtering apparatus, a mechanical stress may be applied to the backing plate and/or the target material, for instance, the backing plate may be previously provided with a camber/bend, or the camber/bend may be corrected after the bonding.

However, as described above, the mechanical and thermal stresses are applied to the conventional backing plate every time by the bonding process. Therefore, while conducting the bonding process repetitively, the backing plate is gradually annealed, so that strength of the backing plate may be lowered, for instance, a camber may be generated, or the lid that is structurally weaker than the main body may be expanded.

Moreover, a distance between the sputtering target and the substrate may be changed due to the deformation of the backing plate, or a heat transfer (cooling) efficiency may be changed because of a local separation of the sputtering target from the backing plate, so that a quality and yield of the formed thin film may be deteriorated.

When the deformation is hardly occurred, the backing plates itself needs to be exchanged, however, if an exchanging interval (lifetime of the backing plate) is short, a frequency of the exchanging work will be increased and it may cause an increase in fabrication cost.

### SUMMARY OF THE INVENTION

Accordingly, it is an object of the present invention to provide a cooling plate that can be used as a backing plate with little local deformation and long operating lifetime.

According to the first feature of the invention, a cooling plate, comprises:

a main body provided with a groove; and

a lid for closing the groove to provide a passage for flowing a coolant;

wherein the lid has a width greater than a width of the groove and is provided with a convex portion at least on one surface.

According to the second feature of the invention, in the cooling plate, the convex portion is provided on an inner surface of the lid.

According to the third feature of the invention, in the cooling plate, the convex portion is provided on an outer surface of the lid.

According to the fourth feature of the invention, in the cooling plate, the convex portion has a width substantially equal to the width of the groove.

According to the fifth feature of the invention, in the cooling plate, the convex portion is provided continuously on a total length of the lid along the groove.

According to the sixth feature of the invention, in the cooling plate, the convex portion is provided intermittently on the lid along the groove.

According to the seventh feature of the invention, in the cooling plate, the groove has a straight portion and a curved portion, and the convex portion of the lid is continuously only on the straight portion of the groove.

According to the eighth feature of the invention, in the cooling plate, the groove has a straight portion and a curved portion, and the convex portion of the lid is intermittently only on the straight portion of the groove.

According to the ninth feature of the invention, in the cooling plate, the convex portion of the lid has a width greater than the width of the groove.

According to the tenth feature of the invention, a cooling plate, comprises:

a main body provided with a groove; and

a lid for closing the groove to provide a passage for flowing a coolant;

wherein the lid has a width greater than a width of the groove and the lid is bonded with the main body by protruding an outer surface of the lid from a surface of the main body.

According to the eleventh feature of the invention, a lid for a cooling plate, comprises:

a lid portion for closing a groove provided in a main body of the cooling plate, the lid portion having a width greater than a width of the groove, and providing a passage cooperatively with the groove for flowing a coolant; and

a convex portion provided at least on one surface of the lid portion.

According to the twelfth feature of the invention, in the lid for a cooling plate, the convex portion is provided on an inner surface of the lid portion.

According to the thirteen feature of the invention, in the lid for a cooling plate, the convex portion is provided on an outer surface of the lid portion.

According to the fourteenth feature of the invention, in the lid for a cooling plate, the convex portion has a width substantially equal to the width of the groove.

According to the fifteenth feature of the invention, in the lid for a cooling plate, the convex portion is provided continuously on a total length of the lid portion along the groove.

According to the sixteenth feature of the invention, in the lid for a cooling plate, the convex portion is provided intermittently on the lid portion along the groove.

According to the seventeenth feature of the invention, in the lid for a cooling plate, the groove has a straight portion and a curved portion, and the convex portion is continuously only on the straight portion of the groove.

According to the eighteenth feature of the invention, in the lid for a cooling plate, the groove has a straight portion and a curved portion, and the convex portion is intermittently only on the straight portion of the groove.

According to the nineteenth feature of the invention, in the lid for a cooling plate, the convex portion has a width greater than the width of the groove.

According to this invention, it is possible to obtain a cooling plate that can be used as a backing plate with little local deformation and long operating lifetime.

### BRIEF DESCRIPTION OF THE DRAWINGS

Preferred embodiment according to the invention will be described in conjunction with appended drawings, wherein:

FIG. 1 is a perspective view showing an example of a conventional backing plate;

FIG. 2 is a partial cross sectional view showing the example of the conventional backing plate in FIG. 1 cut along A-A line;

FIG. 3 is a perspective view of a backing plate in the first preferred embodiment according to the invention;

FIG. 4 is a partial cross sectional view showing the backing plate in the first preferred embodiment according to the invention cut along A-A line in FIG. 3;

FIG. 5 is a side view of a lid constituting the backing plate in the first preferred embodiment according to the invention shown in FIG. 3;

FIG. 6 is a perspective view showing a backing plate of a derivative example in the first preferred embodiment according to the invention;

FIG. 7 is a side view of a lid constituting the backing plate of the derivative example in the first preferred embodiment according to the invention;

FIG. 8 is a partial side view of a lid constituting the backing plate of another derivative example in the first (second) preferred embodiment according to the invention;

FIG. 9 is a partial cross sectional view of a backing plate in the second preferred embodiment according to the invention;

FIG. 10 is a partial cross sectional view of a backing plate in the third preferred embodiment according to the invention; and

FIG. 11 is a cross sectional view of a lid constituting a backing plate in the forth preferred embodiment according to the invention.

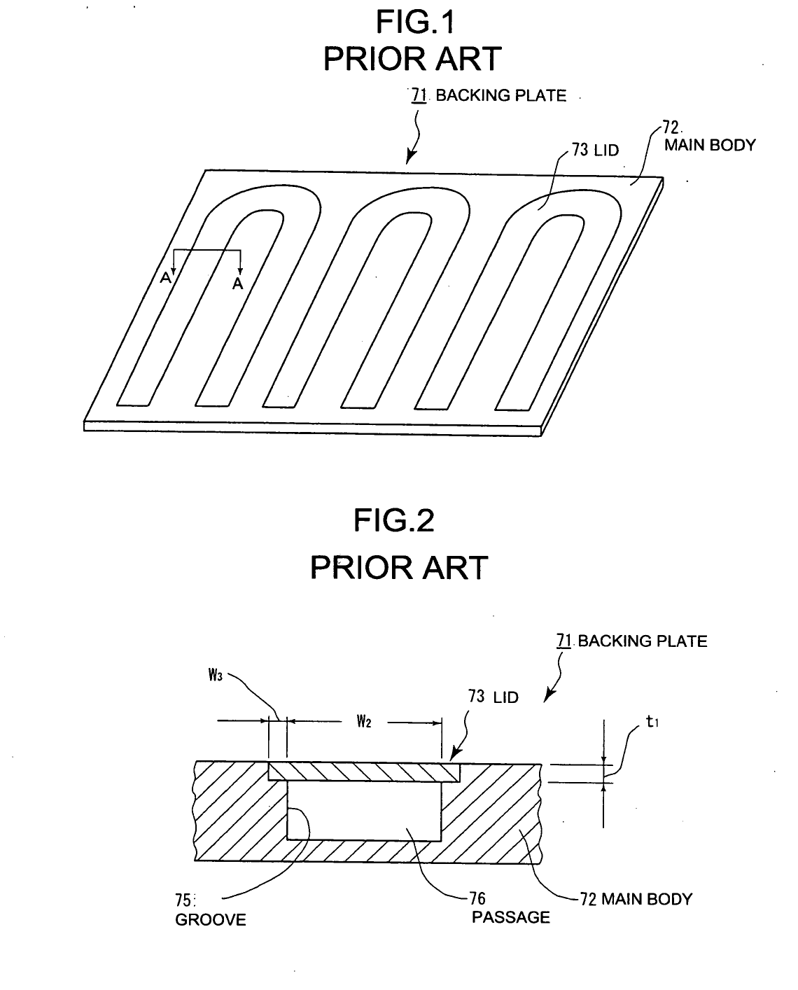

### DETAILED DESCRIPTION OF THE PREFERRED EMBODIMENTS

Next, a backing plate in preferred embodiments according to the invention will be described in more detail.

(Structure of a Backing Plate)

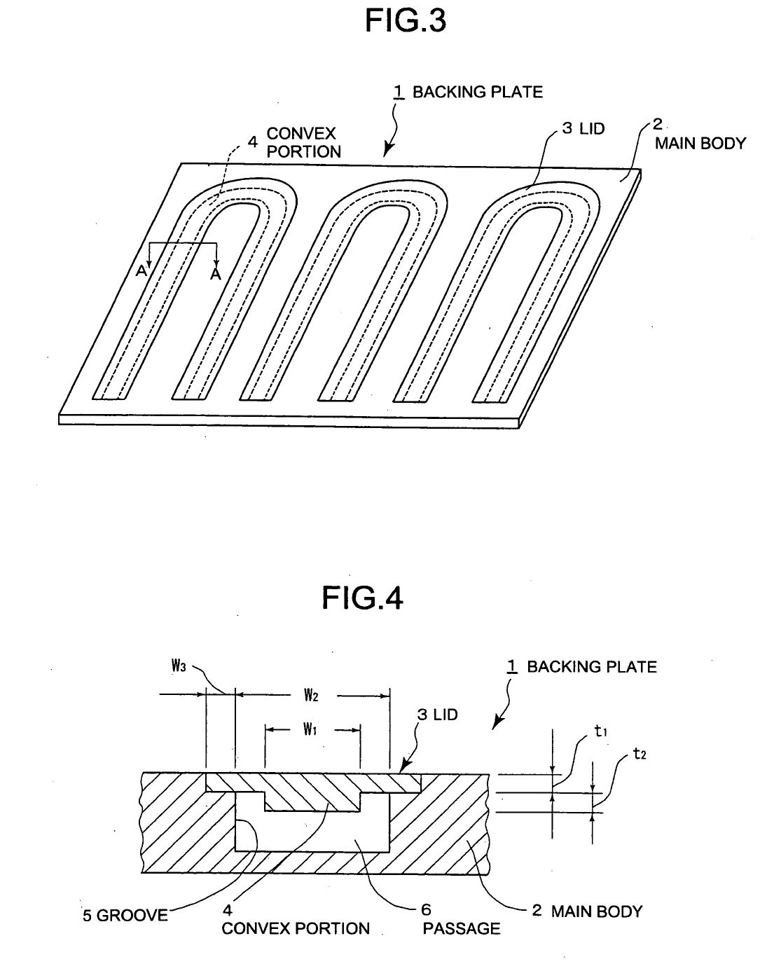

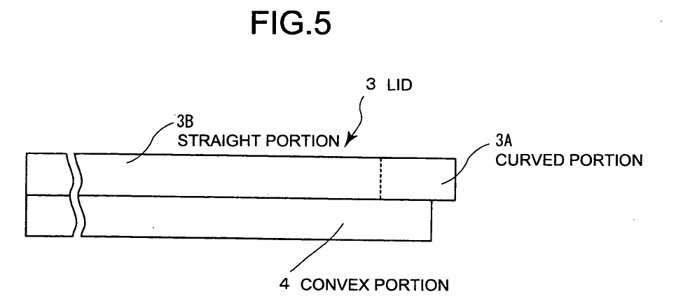

FIGS.3 and 4 show respectively a perspective view and a partial cross sectional view (cut along A-A line in FIG. 3) of the backing plate (the cooling plate) in the first preferred embodiment of this invention. Further, FIG. 5 shows a side view of a lid constituting the backing plate. The structure of the backing plate in the first preferred embodiment will be described below in conjunction with FIGS. 3 to 5.

A backing plate 1 comprises a main body 2 and a lid 3, and the main body 2 is provided with grooves 5 each having a width W₂ and opened to one surface. The lid 3 includes a convex portion 4 (rib) having a width W₁ inside the groove 5. The convex portion 4 is provided at a substantially center of the lid 3 continuously along a total length (in a longitudinal direction) of the lid 3. From the viewpoint of the strength, the width W₁ of the convex portion 4 is preferably less than the width W₂ of the groove 5, and the width W₁ of the convex portion 4 is W₂/4 or more. More preferably, the width W₁ of the convex portion 4 is W₂/3 or more, and most preferably W₂/2 or more.

The lid 3 (which is a part having no convex portion 4) has a thickness t₁ and the convex portion 4 has a thickness t₂. From the viewpoint of obtaining the passage securely, the thickness t₂ is preferably equal to or less than the thickness t₁. From the viewpoint of strength, the thickness t₂ is preferably t₁/4 or more. More preferably, the thickness t₂ is t₁/3 or more, and most preferably t₁/2 or more. The lid 3 has a width of W₂+W₃+W₃, wherein W₃ is a width of an inlaid part.

The lid 3 is engaged in an inlaid structure of the groove 5 of the main body 2, and a space is formed by the lid 3 and the groove 5 inside the main body 2. This space is a passage 6 for flowing a coolant. Although the inlet and the outlet for the coolant are provided on the backing plate 1, the illustration thereof is omitted.

### (Derivative Example of the First Preferred Embodiment)

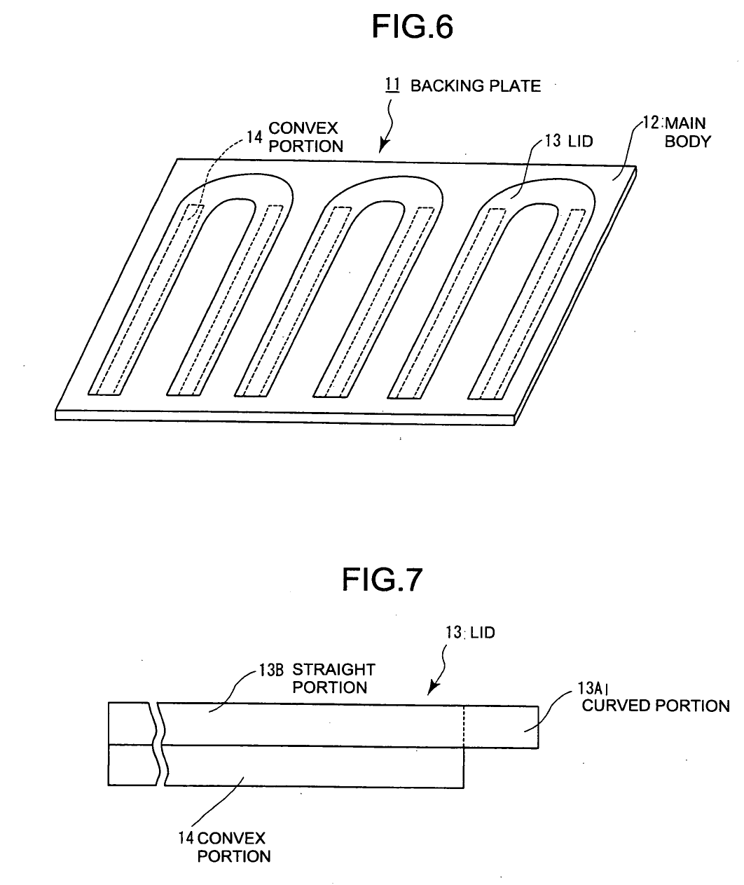

FIG. 6 is a perspective view showing a backing plate of a derivative example in the first preferred embodiment, and FIG. 7 is a side view of the lid constituting this backing plate.

In the backing plate 1 of FIGS. 3 to 5, the convex portion 4 of the lid 3 is provided at a curved portion 3A (specifically a curved portion of the groove 5) and a straight portion 3B (specifically the straight portion of the groove 5). However, in the backing plate 11 shown in FIGS. 6 and 7, a convex portion 14 of a lid 13 is not provided at a curved portion 13A (specifically a curved portion of the groove 5), but is provided only at a straight portion 13B (specifically a straight portion of the groove 5).

### (Another Derivative Example in the First Preferred Embodiment)

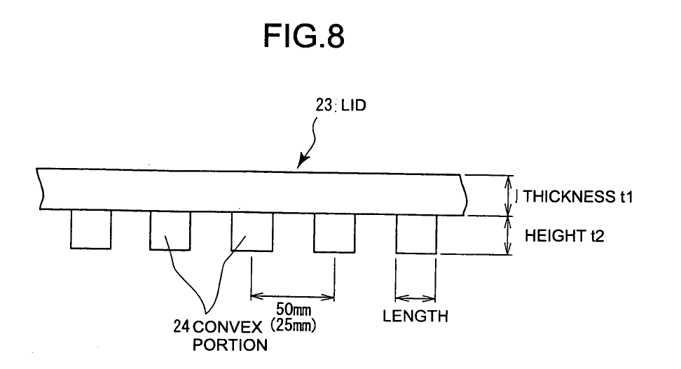

Further, FIG. 8 is a partial side view of a lid constituting a backing plate of another derivative example in the first preferred embodiment.

As shown in FIG. 8, a convex portion 24 provided on a lid 23 is provided intermittently along a total length of the lid 23 or only on its straight portion. When the convex portion 24 is formed on the lid 23 intermittently, an improvement in heat transfer (cooling) efficiency can be expected from the viewpoint of increasing a contact area with the coolant (cooling water) and/or from the viewpoint of generating a turbulent flow in a flow of the coolant.

(Process of Manufacturing the Backing Plate)

The backing plate in the first preferred embodiment can be manufactured by a well-known method described in the related arts except the process of forming the convex portion on the lid.

As the process of forming the convex portion on the lid, various methods can be applied, for instance, a method of forming a convex portion on a lid by cutting work or a method of forming a convex portion separately and bonding (melting or wax welding) on a surface of a lid.

### (Effect of the First Preferred Embodiment) According to the first preferred embodiment, following effects can be obtained.

Strength of a lid against a stress is improved by providing a convex portion on the lid. Therefore, even if a mechanical stress and a heat stress are applied to the lid every time by a bonding process, it is possible to prevent the lid from expanding outwards.

Further, according to the first preferred embodiment, a trouble such as a camber or expansion of the lid does not occur easily, so that a frequency of exchanging the backing plate itself can be reduced and the backing plate can be used as a backing plate with long operating lifetime.

### (Second Preferred Embodiment)

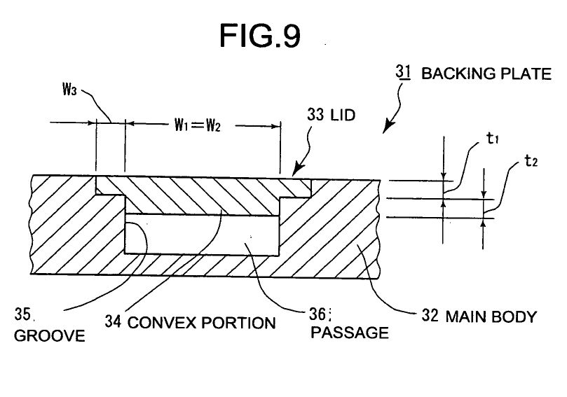

FIG. 9 shows a partial cross sectional view of a backing plate in the second preferred embodiment of this invention. A backing plate 31 as shown in FIG. 9 is different from the backing plate 1 in the first preferred embodiment, only in that a width W₁ of a convex portion 34 on a lid 33 is almost equal to a width W₂ of a groove 35 on a main body 32. As a result, a cooling plate in the second preferred embodiment has higher strength against a stress. The explanations of derivative examples of the second preferred embodiment are omitted, since they are similar to those in the first preferred embodiment.

The strength against the deformation is proportional to a moment of inertia of area (mm⁴) of a part receiving a stress. For instance, in FIG. 8 which is applicable to the second preferred embodiment, the lid has a thickness (t₁) of 3 mm, a cross section of the passage in a water channel has a height of 5 mm and a width of 100 mm, and a convex portion having a height (thickness t₂) of 2.5 mm, a width of 100 mm (in a width direction of the passage) and a length of 10 mm (in a longitudinal direction of the passage) is provided intermittently with an interval of 50 or 25 mm along the passage on the lid. At this time, the moment of inertia of area increases by 3.4 or 4.3 times for the interval of 50 or 25 mm, respectively, compared with the case in which the convex portion is not provided.

### (Third Preferred Embodiment)

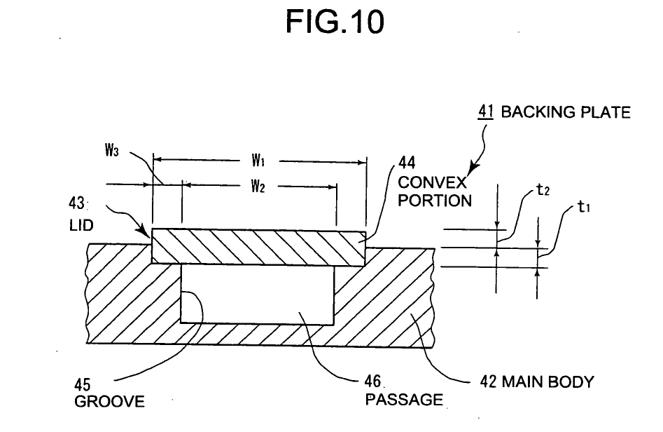

FIG. 10 shows a partial cross sectional view of the backing plate in the third preferred embodiment of this invention. A backing plate 41 as shown in FIG. 10 is different from the backing plate 1 in the first preferred embodiment only in that a lid 43 is bonded to a main body 42 by protruding an outer surface of the lid 43 from a surface of the main body 42 at the same side. The explanations of derivative examples of the third preferred embodiment are omitted, since they are similar to those in the first preferred embodiment.

In the third preferred embodiment, the invention is not limited to a configuration in which the convex portion of the backing plate is provided at an outer surface of the lid according to the first and second preferred embodiments, but also includes a configuration in which a convex portion having a width wider than that of a groove is provided, and a configuration in which a thickness of a lid increases (FIG. 10) etc.

In the backing plate 41 as shown in FIG. 10, a convex portion 44 having a width W₁ is provided and a convex portion 44 has a thickness t₂. A lid 43 has a thickness t₁ and a width of W₂+W₃+W₃, which is equal to the width W₁. An inlaid part has a width W₃.

### (Fourth Preferred Embodiment)

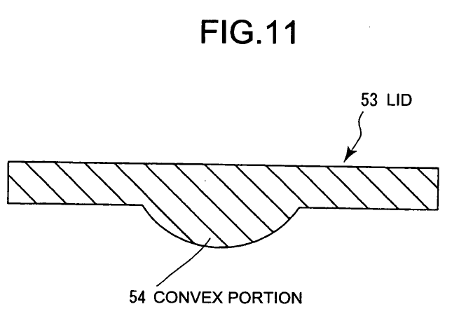

FIG. 11 is a cross sectional view of a lid constituting a backing plate in the fourth preferred embodiment of this invention. A convex portion 54 of a lid 53 has roundness as shown in FIG. 11. Various shapes such as triangle and pentagon can be applied additionally.

### (Fifth Preferred Embodiment)

The first or second preferred embodiment may be combined with the third and/or the fourth preferred embodiment.

In the first to fifth preferred embodiments, the cooling plate as a backing plate is shown. However, the present invention can be also applied to the cooling plate such as various water-cooling jackets and water-cooled chills.

Although the invention has been described with respect to specific embodiment for complete and clear disclosure, the appended claims are not to be thus limited but are to be construed as embodying all modification and alternative constructions that may be occurred to one skilled in the art which fairly fall within the basic teaching herein set forth.

What is claimed is:

1. A cooling plate, comprising:
a main body provided with a groove; and
a lid for closing the groove to provide a passage for flowing a coolant;
wherein the lid has a width greater than a width of the groove and is provided with a convex portion at least on one surface.

2. The cooling plate, according to claim 1, wherein:
the convex portion is provided on an inner surface of the lid.

3. The cooling plate, according to claim 1, wherein:
the convex portion is provided on an outer surface of the lid.

4. The cooling plate, according to claim 2, wherein:
the convex portion has a width substantially equal to the width of the groove.

5. The cooling plate, according to claim 1, wherein:
the convex portion is provided continuously on a total length of the lid along the groove.

6. The cooling plate, according to claim 1, wherein:
the convex portion is provided intermittently on the lid along the groove.

7. The cooling plate, according to claim 1, wherein:
the groove has a straight portion and a curved portion, and the convex portion of the lid is continuously only on the straight portion of the groove.

8. The cooling plate, according to claim 1, wherein:
the groove has a straight portion and a curved portion, and the convex portion of the lid is intermittently only on the straight portion of the groove.

9. The cooling plate, according to claim 3, wherein:
the convex portion of the lid has a width greater than the width of the groove.

10. A cooling plate, comprising:
a main body provided with a groove; and
a lid for closing the groove to provide a passage for flowing a coolant;
wherein the lid has a width greater than a width of the groove and an the lid is bonded with the main body by protruding an outer surface of the lid from a surface of the main body.

11. A lid for a cooling plate, comprising:
a lid portion for closing a groove provided in a main body of the cooling plate, the lid portion having a width greater than a width of the groove, and providing a passage cooperatively with the groove for flowing a coolant; and
a convex-portion provided at least on one surface of the lid portion.

12. The lid for a cooling plate, according to claim 11, wherein:
the convex portion is provided on an inner surface of the lid portion.

13. The lid for a cooling plate, according to claim 11, wherein:
the convex portion is provided on an outer surface of the lid portion.

14. The lid for a cooling plate, according to claim 12, wherein:
the convex portion has a width substantially equal to the width of the groove.

15. The lid for a cooling plate, according to claim 11, wherein:
the convex portion is provided continuously on a total length of the lid portion along the groove.

16. The lid for a cooling plate, according to claim 11, wherein:
the convex portion is provided intermittently on the lid portion along the groove.

17. The lid for a cooling plate, according to claim 11, wherein:
the groove has a straight portion and a curved portion, and the convex portion is continuously only on the straight portion of the groove.

18. The lid for a cooling plate, according to claim 11, wherein:
the groove has a straight portion and a curved portion, and the convex portion is intermittently only on the straight portion of the groove.

19. The lid for a cooling plate, according to claim 13, wherein:
the convex portion has a width greater than the width of the groove.
